(19) United States
(12) Patent Application Publication
(10) Pub. No.: US 2023/0393457 A1
(43) Pub. Date: Dec. 7, 2023

(54) MASK BLANK, PHASE SHIFT MASK, AND METHOD FOR PRODUCING SEMICONDUCTOR DEVICE

(71) Applicant: HOYA CORPORATION, Tokyo (JP)

(72) Inventors: Osamu NOZAWA, Tokyo (JP); Hitoshi MAEDA, Tokyo (JP)

(73) Assignee: HOYA CORPORATION, Tokyo (JP)

(21) Appl. No.: 18/034,656

(22) PCT Filed: Dec. 2, 2021
(86) PCT No.: PCT/JP2021/044247

§ 371 Date: Apr. 28, 2023

(30) Foreign Application Priority Data
Dec. 9, 2020 (JP) 2020-204126

(51) Int. Cl. G03F 1/32

(52) U.S. Cl. CPC G03F 1/32

(57) ABSTRACT

Provided is a mask blank. A mask blank comprising a phase shift film on a transparent substrate, the phase shift film having a structure in which a first layer, a second layer, and a third layer are layered in this order on the transparent substrate, the first layer and the third layer including hafnium and oxygen, and the second layer including silicon and oxygen, wherein when thicknesses of the first layer, the second layer, and the third layer are represented by D₁, D₂, and D₃, respectively, all relationships of (Expression 1-A) to (Expression 1-D) are satisfied, or all relationships of (Expression 2-A) to (Expression 2-D) are satisfied.

### CROSS-REFERENCE TO RELATED APPLICATIONS

This application is the National Stage of International Application No. PCT/JP2021/044247, filed Dec. 2, 2021, which claims priority to Japanese Patent Application No. 2020-204126, filed Dec. 9, 2020, and the contents of which is incorporated by reference.

### TECHNICAL FIELD

The present disclosure relates to a mask blank for a phase shift mask, a phase shift mask, and a method of manufacturing a semiconductor device.

### BACKGROUND ART

In a manufacturing process of a semiconductor device, a fine pattern is formed using a photolithography method. Many transfer masks are usually used for forming the fine pattern. In order to miniaturize the pattern of the semiconductor device, it is necessary to miniaturize the mask pattern formed on the transfer mask and to shorten a wavelength of an exposure light source used in photolithography.

As such a photomask, Patent Document 1 discloses a dielectric mask including a transparent substrate 1 capable of transmitting laser light, a metal film 17 layered on a surface of the transparent substrate 1 and having high reflectance to laser light, a dielectric multilayer thin film 4 formed by alternately layering first and second dielectric members 2 and 3 having different refractive indexes on the metal film 17, and a plurality of openings 18 that are formed through the dielectric multilayer thin film 4 and the metal film 17 and arranged in a predetermined pattern. Patent Document 2 discloses a mask for excimer laser processing having a structure in which a third dielectric layer 1′ is included on an uppermost layer of a dielectric multilayer film obtained by repeatedly forming a combination of bilayer films obtained by building up a first dielectric layer 1 and a second dielectric layer 2 on a surface of a glass substrate 3 opposite to an ultraviolet light incident side and a metal film 4 is provided on the uppermost layer, the glass substrate 3 being transparent to ultraviolet light, the first dielectric layer 1 having a film thickness with an optical path length of ¼ wavelength of ultraviolet light to be used, the second dielectric layer 2 having an optical path length of ¼ wavelength and a refractive index smaller than that of the first dielectric layer, the third dielectric layer 1′ having a refractive index larger than the refractive index of the glass substrate and having an optical path length of ¼ wavelength of ultraviolet light to be used.

In Patent Documents 1 and 2, a KrF excimer laser (wavelength: 248 nm) is mainly applied to an exposure light source when manufacturing a semiconductor device. However, in recent years, an ArF excimer laser (wavelength: 193 nm) has been increasingly applied to an exposure light source when manufacturing a semiconductor device.

One type of a transfer mask is a halftone phase shift mask. As a mask blank for the halftone phase shift mask, there has been conventionally known a mask blank having a structure in which a phase shift film made of a material containing silicon and nitrogen, a light-shielding film made of a chromium-based material, and an etching mask film (hard mask film) made of an inorganic material are layered on a transparent substrate. In a case where the halftone phase shift mask is manufactured using this mask blank, first, an etching mask film is patterned by dry etching with a fluorine-based gas using a resist pattern formed on a surface of the mask blank as a mask, then a light-shielding film is patterned by dry etching with a mixed gas of chlorine and oxygen using the etching mask film as a mask, and further, a phase shift film is patterned by dry etching with a fluorine-based gas using the pattern of the light-shielding film as a mask.

### PRIOR ART DOCUMENTS

### Patent Documents

Patent Document 1: JP H07-325384 A
Patent Document 2: JP H08-171197 A

### SUMMARY OF DISCLOSURE

### Technical Problem

With miniaturization and complication of patterns in recent years, in order to enable pattern transfer with higher resolution, a phase shift film with higher transmittance (for example, 35% or more) with respect to exposure light of an ArF excimer laser is expected. By increasing the transmittance with respect to the exposure light, a phase shift effect can be enhanced. With miniaturization and the like of the pattern, from the viewpoint of restraining pattern collapse and the like, it is expected to control a film thickness of the phase shift film to a certain level or less (for example, to 60 nm or less).

The present disclosure has been made to solve the conventional problems, and an aspect thereof is to provide a mask blank which enables: higher transmittance with respect to exposure light of an ArF excimer laser with a certain level or more (for example, 35% or more) to enhance a phase shift effect; a film thickness of a phase shift film controlled to a certain level or less (for example, 60 nm or less); and manufacture of a phase shift mask having excellent optical performance. An aspect of the present disclosure is to provide a phase shift mask which enables: higher transmittance with respect to exposure light of an ArF excimer laser with a certain level or more to enhance a phase shift effect; and a film thickness of a phase shift film controlled to a certain level or less, the phase shift mask having excellent optical performance. The present disclosure provides a method of manufacturing a semiconductor device using such a phase shift mask.

### Solution to Problem

The present disclosure has the following configurations as means for solving the above problems.

### (Configuration 1)

A mask blank including a phase shift film on a transparent substrate,
the phase shift film having a structure in which a first layer, a second layer, and a third layer are layered in this order on the transparent substrate,
the first layer and the third layer including hafnium and oxygen, and
the second layer including silicon and oxygen, wherein
when thicknesses of the first layer, the second layer, and the third layer are represented by D₁, D₂, and D₃, respectively, all relationships of (Expression 1-A) to (Expression 1-D) are satisfied, or all relationships of (Expression 2-A) to (Expression 2-D) are satisfied.

D₁≥4.88×10⁻⁴×D₂⁴−2.91×10⁻²×D₂³+0.647×D₂²−6.51×D₂+26.8 (Expression 1-A)

D₁≤−4.80×10⁻⁴×D₂⁴+2.86×10⁻²×D₂³−0.630×D₂²+5.97×D₂−10.0 (Expression 1-B)

D₃≥4.41×10⁻⁴×D₂⁴−2.66×10⁻²×D₂³+0.598×D₂²−6.13×D₂+59.3 (Expression 1-C)

D₃≤−4.72×10⁻⁴×D₂⁴+2.81×10⁻²×D₂³−0.625×D₂²+6.97×D₂+23.0 (Expression 1-D)

D₁≥5.14×10⁻⁴×D₂⁴−2.96×10⁻²×D₂³+0.634×D₂²−6.17×D₂+57.8 (Expression 2-A)

D₁≤−4.23×10⁻⁴×D₂⁴+2.57×10⁻²×D₂³−0.580×D₂²+5.71×D₂+25.8 (Expression 2-B)

D₃≥5.76×10⁻⁴×D₂⁴−3.23×10⁻²×D₂³+0.673×D₂²−6.33×D₂+23.7 (Expression 2-C)

D₃≤−4.76×10⁻⁴×D₂⁴+2.74×10⁻²×D₂³−0.579×D₂²+5.13×D₂−6.29 (Expression 2-D)

### (Configuration 2)

The mask blank according to configuration 1, wherein the thickness D₂ of the second layer is 20 nm or less.

### (Configuration 3)

The mask blank according to configuration 1 or 2, wherein a total content of hafnium and oxygen in each of the first layer and the third layer is 90 atom % or more.

### (Configuration 4)

The mask blank according to any one of configurations 1 to 3, wherein a total content of silicon and oxygen in the second layer is 90 atom % or more.

### (Configuration 5)

The mask blank according to any one of configurations 1 to 4, wherein a content of oxygen in each of the first layer, the second layer, and the third layer is 50 atom % or more.

### (Configuration 6)

The mask blank according to any one of configurations 1 to 5, wherein a refractive index n of each of the first layer and the third layer with respect to a wavelength of light of an ArF excimer laser is 2.5 or more and 3.1 or less.

### (Configuration 7)

The mask blank according to any one of configurations 1 to 6, wherein a refractive index n of the second layer with respect to a wavelength of light of an ArF excimer laser is 1.5 or more and 2.0 or less.

### (Configuration 8)

The mask blank according to any one of configurations 1 to 7, wherein an extinction coefficient k of each of the first layer and the third layer with respect to a wavelength of light of an ArF excimer laser is 0.05 or more and 0.4 or less.

### (Configuration 9)

The mask blank according to any one of configurations 1 to 8, wherein an extinction coefficient k of the second layer with respect to a wavelength of light of an ArF excimer laser is less than 0.05.

### (Configuration 10)

The mask blank according to any one of configurations 1 to 9, wherein the thickness of the third layer is 5 nm or more.

### (Configuration 11)

The mask blank according to any one of configurations 1 to 9, further comprising a fourth layer on the third layer, wherein a total content of silicon and oxygen in the fourth layer is 90 atom % or more.

### (Configuration 12)

The mask blank according to any one of configurations 1 to 11, wherein the phase shift film has a function of transmitting exposure light of an ArF excimer laser with transmittance of 35% or more, and a function of generating a phase difference of 150 degrees or more and 210 degrees or less between the exposure light transmitted through the phase shift film and the exposure light transmitted through air by the same distance as a thickness of the phase shift film.

### (Configuration 13)

A phase shift mask including a phase shift film on which a transfer pattern is formed on a transparent substrate,
the phase shift film having a structure in which a first layer, a second layer, and a third layer are layered in this order on the transparent substrate,
the first layer and the third layer including hafnium and oxygen, and
the second layer including silicon and oxygen, wherein
when thicknesses of the first layer, the second layer, and the third layer are represented by D₁, D₂, and D₃, respectively, all relationships of (Expression 1-A) to (Expression 1-D) are satisfied, or all relationships of (Expression 2-A) to (Expression 2-D) are satisfied.

D₁≥4.88×10⁻⁴×D₂⁴−2.91×10⁻²×D₂³+0.647×D₂²−6.51×D₂+26.8 (Expression 1-A)

D₁≥−4.80×10⁻⁴×D₂⁴+2.86×10⁻²×D₂³−0.630×D₂²+5.97×D₂−10.0 (Expression 1-B)

D₃≥4.41×10⁻⁴×D₂⁴−2.66×10⁻²×D₂³+0.598×D₂²−6.13×D₂+59.3 (Expression 1-C)

D₃≤−4.72×10⁻⁴×D₂⁴+2.81×10⁻²×D₂³−0.625×D₂²+6.97×D₂+23.0 (Expression 1-D)

D₁≥5.14×10⁻⁴×D₂⁴−2.96×10⁻²×D₂³+0.634×D₂²−6.17×D₂+57.8 (Expression 2-A)

D₁≤−4.23×10⁻⁴×D₂⁴+2.57×10⁻²×D₂³−0.580×D₂²+5.71×D₂+25.8 (Expression 2-B)

D₃≥5.76×10⁻⁴×D₂⁴−3.23×10⁻²×D₂³+0.673×D₂²−6.33×D₂+23.7 (Expression 2-C)

D₃≤−4.76×10⁻⁴×D₂⁴+2.74×10⁻²×D₂³−0.579×D₂²+5.13×D₂−6.29 (Expression 2-D)

### (Configuration 14)

The phase shift mask according to configuration 13, wherein the thickness D₂ of the second layer is 20 nm or less.

### (Configuration 15)

The phase shift mask according to configuration 13 or 14, wherein a total content of hafnium and oxygen in each of the first layer and the third layer is 90 atom % or more.

### (Configuration 16)

The phase shift mask according to any one of configuration 13 to 15, wherein a total content of silicon and oxygen in the second layer is 90 atom % or more.

### (Configuration 17)

The phase shift mask according to any one of configurations 13 or 16, wherein a content of oxygen in each of the first layer, the second layer, and the third layer is 50 atom % or more.

### (Configuration 18)

The phase shift mask according to any one of configurations 13 to 17, wherein a refractive index n of each of the first layer and the third layer with respect to a wavelength of light of an ArF excimer laser is 2.5 or more and 3.1 or less.

### (Configuration 19)

The phase shift mask according to any one of configurations 13 to 18, wherein a refractive index n of the second layer with respect to a wavelength of light of an ArF excimer laser is 1.5 or more and 2.0 or less.

### (Configuration 20)

The phase shift mask according to any one of configurations 13 to 19, wherein an extinction coefficient k of each of the first layer and the third layer with respect to a wavelength of light of an ArF excimer laser is 0.05 or more and 0.4 or less.

### (Configuration 21)

The phase shift mask according to any one of configurations 13 to 20, wherein an extinction coefficient k of the second layer with respect to a wavelength of light of an ArF excimer laser is less than 0.05.

### (Configuration 22)

The phase shift mask according to any one of configurations 13 to 21, wherein the thickness of the third layer is 5 nm or more.

### (Configuration 23)

The phase shift mask according to any one of configurations 13 to 22, further comprising a fourth layer on the third layer, wherein a total content of silicon and oxygen in the fourth layer is 90 atom % or more.

### (Configuration 24)

The phase shift mask according to any one of configurations 13 to 23, wherein the phase shift film has a function of transmitting exposure light of an ArF excimer laser with transmittance of 35% or more, and a function of generating a phase difference of 150 degrees or more and 210 degrees or less between the exposure light transmitted through the phase shift film and the exposure light transmitted through air by the same distance as a thickness of the phase shift film.

### (Configuration 25)

The phase shift mask according to any one of configurations 13 to 24, comprising a light-shielding film on which a light-shielding pattern is formed on the phase shift film.

### (Configuration 26)

A method of manufacturing a semiconductor device, the method comprising transferring a transfer pattern by exposure to a resist film on a semiconductor substrate using the phase shift mask according to any one of configurations 13 to 25.

### Advantageous Effects of Disclosure

A mask blank according to the present disclosure having the above-described configuration is a mask blank including a phase shift film on a transparent substrate, the phase shift film having a structure in which a first layer, a second layer, and a third layer are layered in this order on the transparent substrate, the first layer and the third layer containing hafnium and oxygen, and the second layer containing silicon and oxygen, wherein when thicknesses of the first layer, the second layer, and the third layer are represented by D₁, D₂, and D₃, respectively, all relationships of (Expression 1-A) to (Expression 1-D) are satisfied, or all relationships of (Expression 2-A) to (Expression 2-D) are satisfied. Therefore, it is possible to manufacture a phase shift mask which enables higher transmittance with respect to exposure light of an ArF excimer laser with a certain level or more to enhance a phase shift effect, and a film thickness of a phase shift film controlled to a certain level or less, the phase shift mask having excellent optical performance. Furthermore, when manufacturing a semiconductor device using this phase shift mask, it is possible to accurately transfer a pattern to a resist film and the like on the semiconductor device.

### BRIEF DESCRIPTION OF DRAWINGS

FIG. 1 is a schematic cross-sectional view of a mask blank according to a first embodiment.

FIG. 2 is a schematic cross-sectional view of a mask blank according to a second embodiment.

FIGS. 3A-3G are schematic cross-sectional views illustrating a manufacturing process of a phase shift mask of the first and second embodiments.

FIG. 4 is a graph illustrating a relationship between a thickness of a first layer and a thickness of a second layer that satisfy desired transmittance, phase difference, and film thickness of a phase shift film derived from simulation results.

FIG. 5 is a graph illustrating a relationship between a thickness of a second layer and a thickness of a third layer that satisfy desired transmittance, phase difference, and film thickness of a phase shift film derived from simulation results.

### DESCRIPTION OF EMBODIMENTS

Hereinafter, each embodiment of the present disclosure will be described. The inventors of the present application have intensively conducted studies on a phase shift film regarding a configuration capable of increasing transmittance with respect to exposure light of an ArF excimer laser (hereinafter sometimes simply referred to as exposure light) to a certain level or more (for example, 35% or more) to enhance a phase shift effect, and controlling a film thickness of the phase shift film to a certain level or less (for example, 60 nm or less), the configuration having excellent optical performance.

The phase shift film needs to have both a function of transmitting the exposure light with predetermined transmittance and a function of generating a predetermined phase difference between the exposure light transmitted through the phase shift film and exposure light transmitted through air by the same distance as the thickness of the phase shift film. When an attempt is made to control the film thickness of the phase shift film to a certain level or less, it becomes difficult to secure a desired phase difference. The phase shift film having a single-layer structure or a two-layer structure has a low degree of freedom in design, and it has not been easy to increase the transmittance to a certain level or more (for example, 35% or more) and control the film thickness of the phase shift film to a certain level or less (for example, 60 nm or less) while securing the desired phase difference.

Therefore, the inventors of the present application have studied to make the phase shift film have a three-layer structure. In addition, the inventors have found that, when the phase shift film includes a first layer, a second layer, and a third layer from a transparent substrate side, by adopting a configuration in which the first and third layers contain hafnium and oxygen and the second layer contains silicon and oxygen, the desired phase difference can be secured and the film thickness can be controlled to be small. A thin film containing hafnium and oxygen has an optical characteristic in which a refractive index n with respect to the exposure light is significantly large but an extinction coefficient k is relatively small. A thin film containing silicon and oxygen has an optical characteristic in which the refractive index n with respect to the exposure light is relatively small but the extinction coefficient k is significantly small. It was initially considered that desired transmittance, phase difference, and film thickness can be freely set by forming a multilayer structure in which these thin films are combined. However, it has been found that, under this condition alone, even if the film thickness of an entire phase shift film is equivalent, there is a case where the desired transmittance of a certain level or more cannot be obtained when adjustment is made so as to obtain the desired phase difference.

The present inventor has further conducted studies, and found that a thickness of each layer of the above-described three-layer structure is important in order to obtain the desired transmittance of a certain level or more. Therefore, optical simulation was performed on the thicknesses of the first layer, the second layer, and the third layer in order to satisfy that the transmittance with respect to the exposure light in the three-layer structure of the phase shift film is 35% or more, that the film thickness is 60 nm or less, and that the phase difference is substantially 180°. Specifically, under the condition that the film thickness of the phase shift film was within a predetermined range of 60 nm or less and that the phase difference was within a predetermined range of substantially 180°, the transmittance of the phase shift film was calculated while the thicknesses of the first layer and the third layer were changed with the thickness of the second layer fixed. Then, the thickness of the second layer was sequentially changed within a predetermined range, and the above-described processing was sequentially performed.

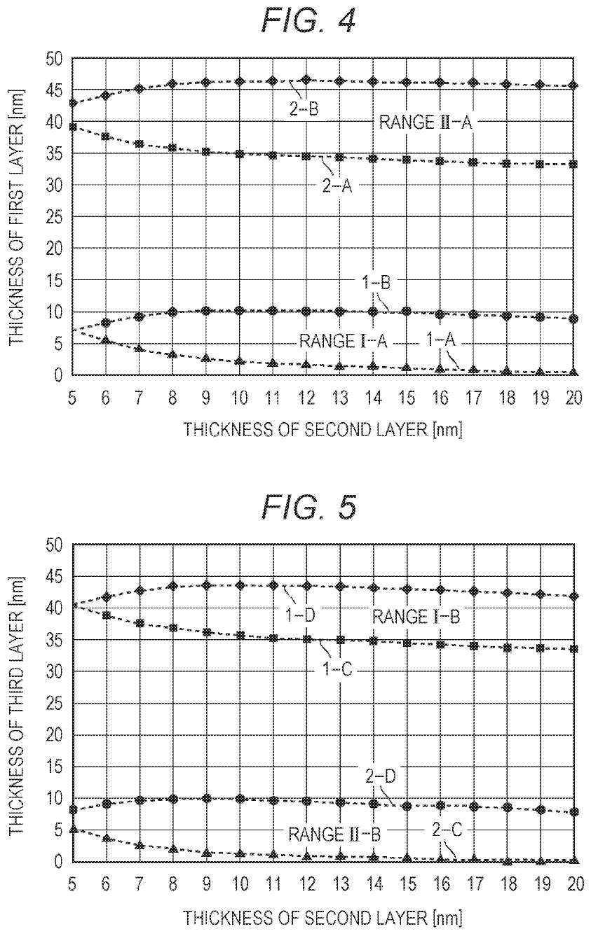

According to these optical simulations, a relationship among the first layer, the second layer, and the third layer of the phase shift film was organized, the phase shift film having the desired transmittance (35% or more in this simulation). As a result, a certain relationship was obtained in each of a case where the first layer was thicker than the third layer and a case where the first layer was thinner than the third layer. FIGS. 4 and 5 illustrate the relationship between the thickness of the first layer and the thickness of the second layer, and the relationship between the thickness of the second layer and the thickness of the third layer, respectively, that satisfy the desired transmittance, phase difference, and film thickness of the phase shift film derived from simulation results.

In FIGS. 4 and 5, it has been found that, when the thicknesses of the first layer and the second layer are in a region defined by curves 1-A and 1-B (that is, a range I-A interposed between the curve 1-A and curve 1-B in FIG. 4) and the thicknesses of the second layer and the third layer are in a region defined by curves 1-C and 1-D (that is, a range I-B interposed between the curve 1-C and curve 1-D in FIG. 5), all the conditions of the desired transmittance, phase difference, and film thickness of the phase shift film are satisfied. At that time, as can be grasped from FIGS. 4 and 5, the first layer is thinner than the third layer.

In FIGS. 4 and 5, it has been found that, when the thicknesses of the first layer and the second layer are in a region defined by curves 2-A and 2-B (that is, a range II-A interposed between the curve 2-A and curve 2-B in FIG. 4), and the thicknesses of the second layer and the third layer are in a region defined by curves 2-C and 2-D (that is, a range II-B interposed between the curve 2-C and curve 2-D in FIG. 5), all the conditions of the desired transmittance, phase difference, and film thickness of the phase shift film are satisfied. At that time, as can be grasped from FIGS. 4 and 5, the first layer is thicker than the third layer.

The present disclosure has been made as a result of the intensive studies as described above.

Hereinafter, a detailed configuration of the present disclosure described above will be described with reference to the drawings. Note that, in the drawings, similar components are denoted by the same reference numerals to be described.

### First Embodiment

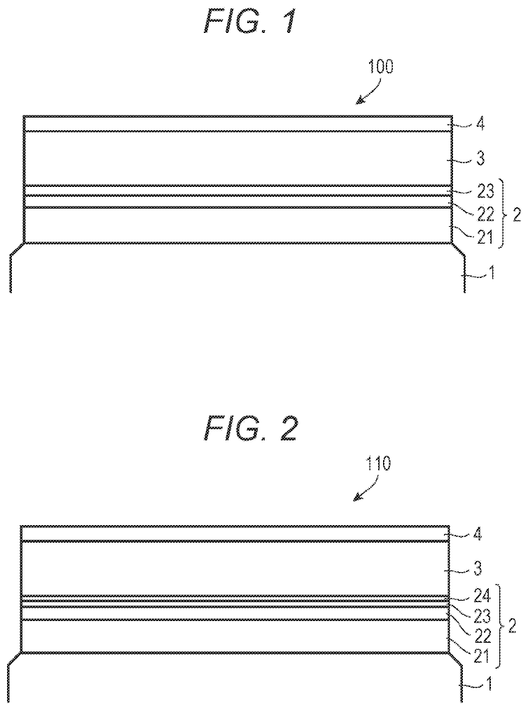

FIG. 1 illustrates a schematic configuration of a mask blank according to a first embodiment. A mask blank 100 illustrated in FIG. 1 has a configuration in which a phase shift film 2, a light-shielding film 3, and a hard mask film 4 are layered in this order on one main surface of a transparent substrate 1. The mask blank 100 may have a configuration without the hard mask film 4 as necessary. The mask blank 100 may also have a configuration in which a resist film is layered on the hard mask film 4 as necessary. Hereinafter, details of main components of the mask blank 100 will be described.

### [Transparent Substrate]

The transparent substrate 1 is made of a material excellent in transparency with respect to exposure light used in an exposure process in lithography. As such material, synthetic quartz glass, aluminosilicate glass, soda lime glass, low thermal expansion glass (SiO₂—TiO₂ glass and the like), and other various glass substrates can be used. In particular, a substrate in which synthetic quartz glass is used has high transparency to ArF excimer laser light (wavelength: about 193 nm), so that this can be suitably used as the transparent substrate 1 of the mask blank 100.

Note that, the exposure process in lithography as used herein is an exposure process in lithography using a phase shift mask produced using the mask blank 100, and the exposure light refers to ArF excimer laser light (wavelength: 193 nm) unless otherwise specified.

A refractive index of the material forming the transparent substrate 1 with respect to the exposure light is preferably 1.5 or more and 1.6 or less, more preferably 1.52 or more and 1.59 or less, and still more preferably 1.54 or more and 1.58 or less.

### [Phase Shift Film]

The phase shift film 2 preferably has a function of transmitting the exposure light with transmittance of 35% or more, and more preferably 37% or more. This is for generating a sufficient phase shift effect between the exposure light transmitted through the inside of the phase shift film 2 and the exposure light transmitted through air. The transmittance of the phase shift film 2 with respect to the exposure light is preferably 60% or less, and more preferably 50% or less. This is for controlling a film thickness of the phase shift film 2 in an appropriate range in which optical performance can be secured.

In order to obtain an appropriate phase shift effect, the phase shift film 2 is preferably adjusted so as to have a function of generating a phase difference of 150 degrees or more and 210 degrees or less between the exposure light transmitted through the phase shift film 2 and the exposure light transmitted through the air by the same distance as the thickness of the phase shift film 2. The phase difference in the phase shift film 2 is more preferably 155 degrees or more, and still more preferably 160 degrees or more. On the other hand, the phase difference in the phase shift film 2 is more preferably 195 degrees or less, and still more preferably 190 degrees or less.

The phase shift film 2 in the present embodiment has a structure in which a first layer 21, a second layer 22, and a third layer 23 are layered from the transparent substrate 1 side.

The phase shift film 2 in the present embodiment satisfies all of relationships of (Expression 1-A) to (Expression 1-D) or satisfies all of relationships of (Expression 2-A) to (Expression 2-D), where thicknesses of the first layer 21, the second layer 22, and the third layer 23 are represented by D₁, D₂, and D₃, respectively.

D₁≥4.88×10⁻⁴×D₂⁴−2.91×10⁻²×D₂³+0.647×D₂²−6.51×D₂+26.8 (Expression 1-A)

D₁≥−4.80×10⁻⁴×D₂⁴+2.86×10⁻²×D₂³−0.630×D₂²+5.97×D₂−10.0 (Expression 1-B)

D₃≥4.41×10⁻⁴×D₂⁴−2.66×10⁻²×D₂³+0.598×D₂²−6.13×D₂+59.3 (Expression 1-C)

D₃≤−4.72×10⁻⁴×D₂⁴+2.81×10⁻²×D₂³−0.625×D₂²+6.97×D₂+23.0 (Expression 1-D)

D₁≥5.14×10⁻⁴×D₂⁴−2.96×10⁻²×D₂³+0.634×D₂²−6.17×D₂+57.8 (Expression 2-A)

D₁≤−4.23×10⁻⁴×D₂⁴+2.57×10⁻²×D₂³−0.580×D₂²+5.71×D₂+25.8 (Expression 2-B)

D₃≥5.76×10⁻⁴×D₂⁴−3.23×10⁻²×D₂³+0.673×D₂²−6.33×D₂+23.7 (Expression 2-C)

D₃≤−4.76×10⁻⁴×D₂⁴+2.74×10⁻²×D₂³−0.579×D₂²+5.13×D₂−6.29 (Expression 2-D)

In (Expression 1-A) to (Expression 1-D) and (Expression 2-A) to (Expression 2-D) described above, the expressions with equal sign correspond to the curves 1-A to 1-D and curves 2-A to 2-D illustrated in FIGS. 4 and 5. That is, when (Expression 1-A) to (Expression 1-D) described above are satisfied, the thicknesses D₁ to D₃ of the first layer 21 to the third layer 23 fall within the ranges I-A and I-B illustrated in FIGS. 4 and 5. When (Expression 2-A) to (Expression 2-D) described above are satisfied, the thicknesses D₁ to D₃ of the first layer 21 to the third layer 23, respectively, fall within the ranges II-A and II-B illustrated in FIGS. 4 and 5.

In order to secure the optical performance, the film thickness of the phase shift film 2 is preferably 65 nm or less, and more preferably 60 nm or less. The film thickness of the phase shift film 2 is preferably 45 nm or more and more preferably 50 nm or more in order to secure a function of generating a desired phase difference.

The first layer 21 and the third layer 23 preferably contain hafnium and oxygen, and more preferably consist of hafnium and oxygen. Here, the phrase “consist of hafnium and oxygen” refers to materials containing, in addition to these constituent elements, only elements (noble gases such as helium (He), neon (Ne), argon (Ar), krypton (Kr), and xenon (Xe), hydrogen (H), carbon (C) and the like) that are inevitably contained in the first layer 21 and the third layer 23 when a film is formed by a sputtering method (the same applies to the description of “consist of silicon and oxygen” in the second layer 22 and the fourth layer 24 to be described). By minimizing the presence of other elements that bond to hafnium in the first layer 21 and the third layer 23, a ratio of bonds of hafnium and oxygen in the first layer 21 and the third layer 23 can be significantly increased.

Therefore, a total content of hafnium and oxygen in each of the first layer 21 and the third layer 23 is preferably 90 atom % or more, more preferably 95 atom % or more, and still more preferably 98 atom % or more. A content of oxygen in each of the first layer 21 and the third layer 23 is preferably 50 atom % or more, more preferably 55 atom % or more, and still more preferably 60 atom % or more. A total content of the above-described elements (noble gas, hydrogen, carbon and the like) inevitably contained in the first layer 21 and the third layer 23 is preferably 3 atom % or less.

The refractive index n of the first layer 21 and the third layer 23 with respect to the exposure light is preferably 3.1 or less, and more preferably 3.0 or less. The refractive index n of the first layer 21 and the third layer 23 is preferably 2.5 or more, and more preferably 2.6 or more. In contrast, the first layer 21 and the third layer 23 preferably has an extinction coefficient k with respect to the exposure light of 0.4 or less. This is for increasing the transmittance of the phase shift film 2 with respect to the exposure light. The extinction coefficient k of the first layer 21 and the third layer 23 is preferably 0.05 or more, more preferably 0.1 or more, and still more preferably 0.2 or more.

In a case where (Expression 1-A) and (Expression 1-B) described above are satisfied, the thickness D₁ of the first layer 21 is preferably 1 nm or more, and more preferably 2 nm or more. The thickness D₁ is preferably 10 nm or less, and more preferably 9 nm or less.

In a case where (Expression 2-A) and (Expression 2-B) described above are satisfied, the thickness D₁ of the first layer 21 is preferably 33 nm or more, and more preferably 34 nm or more. The thickness D₁ is preferably 46 nm or less, and more preferably 45 nm or less.

In a case where (Expression 1-C) and (Expression 1-D) described above are satisfied, the thickness D₃ of the third layer 23 is preferably 34 nm or more, and more preferably 35 nm or more. The thickness D₃ is preferably 44 nm or less, and more preferably 43 nm or less.

In a case where (Expression 2-C) and (Expression 2-D) described above are satisfied, the thickness D₃ of the third layer 23 is preferably 1 nm or more, and more preferably 2 nm or more. The thickness D₃ is preferably 10 nm or less, and more preferably 9 nm or less.

In contrast, in a case where (Expression 2-C) and (Expression 2-D) described above are satisfied, the thickness D₃ of the third layer 23 is preferably 5 nm or more, and more preferably 6 nm or more from the viewpoint of chemical resistance and cleaning resistance. The thickness D₃ is preferably 10 nm or less, and more preferably 9 nm or less. In a case where the thickness D₃ of the third layer 23 containing hafnium and oxygen is less than 5 nm, mutual diffusion generated at an interface between the third layer 23 and the second layer containing silicon and oxygen easily spreads over an entire third layer 23. A thin film containing hafnium, silicon, and oxygen has low chemical resistance and cleaning resistance. In the third layer 23 in which the mutual diffusion spreads entirely, the chemical resistance and cleaning resistance are deteriorated. When the thickness of the third layer 23 is 5 nm or more, it is possible to restrain the mutual diffusion over the entire third layer 23, and thereby the deterioration in chemical resistance and cleaning resistance of the third layer 23 can be restrained.

The second layer 22 preferably contains silicon and oxygen, and more preferably consists of silicon and oxygen. By minimizing the presence of other elements that bond to silicon in the second layer 22, a ratio of bonds of silicon and oxygen in the second layer 22 can be significantly increased.

Therefore, a total content of silicon and oxygen in the second layer 22 is preferably 90 atom % or more, more preferably 95 atom % or more, and still more preferably 98 atom % or more. A content of oxygen in the second layer 22 is preferably 50 atom % or more, more preferably 55 atom % or more, and still more preferably 60 atom % or more. A total content of the above-described elements (noble gas, hydrogen, carbon and the like) inevitably contained in the second layer 22 is preferably 3 atom % or less.

The refractive index n of the second layer 22 with respect to the exposure light is preferably 2.0 or less, and more preferably 1.8 or less. The refractive index n of the second layer 22 is preferably 1.5 or more, and more preferably 1.52 or more. In contrast, the second layer 22 is expected to have the extinction coefficient k with respect to the exposure light smaller than those of the first layer 21 and the third layer 23. The extinction coefficient k of the second layer 22 is preferably less than 0.05, and more preferably 0.02 or less. This is for increasing the transmittance of the phase shift film 2 with respect to the exposure light.

In a case where (Expression 1-A) to (Expression 1-D) described above are satisfied or (Expression 2-A) to (Expression 2-D) described above are satisfied, the thickness D₂ of the second layer 22 is preferably 5 nm or more, and more preferably 7 nm or more. In order to restrain the film thickness of the phase shift film 2, the thickness D₂ is preferably 20 nm or less, and more preferably 18 nm or less.

The phase shift film 2 more preferably has a configuration in which the first layer 21 is thicker than the third layer 23. At the time of patterning of the phase shift film 2, for the reason of enhancing perpendicularity of a pattern sidewall to be formed and the like, so-called over etching is performed in which dry etching is continued even after etching of the phase shift film 2 reaches the surface of the transparent substrate 1. In the over etching, the transparent substrate 1 side of the pattern sidewall formed on the phase shift film 2 is mainly etched. Because the second layer 22 contains silicon and oxygen, an etching rate of the second layer 22 for dry etching is lower than that of the first layer 21. In a case where the first layer 21 is thick, a ratio of the first layer 21 is relatively high on the transparent substrate 1 side of the pattern sidewall of the phase shift film 2. In that case, it is easy to control the perpendicularity of the pattern sidewall of the phase shift film 2 by over etching.

The refractive index n and the extinction coefficient k of a thin film including the phase shift film 2 are not determined only by composition of the thin film. Film density, a crystal state and the like of the thin film are also factors that affect the refractive index n and the extinction coefficient k. Therefore, various conditions are adjusted when forming a thin film by reactive sputtering, such that the thin film is formed so as to have desired refractive index n and extinction coefficient k. In order to make the phase shift film 2 have the refractive index n and the extinction coefficient k which fall within the above-described range, it is not limited to adjusting a ratio of a mixed gas of the noble gas and a reactive gas (oxygen gas, nitrogen gas and the like) at the time of film formation by the reactive sputtering. There are a variety of conditions such as a pressure in a film forming chamber when the film is formed by the reactive sputtering, power applied to a sputtering target, and a positional relationship such as a distance between the target and the transparent substrate 1. These film forming conditions are unique to a film forming apparatus, and are adjusted as appropriate so that the thin film to be formed has the desired refractive index n and extinction coefficient k.

### [Light-Shielding Film]

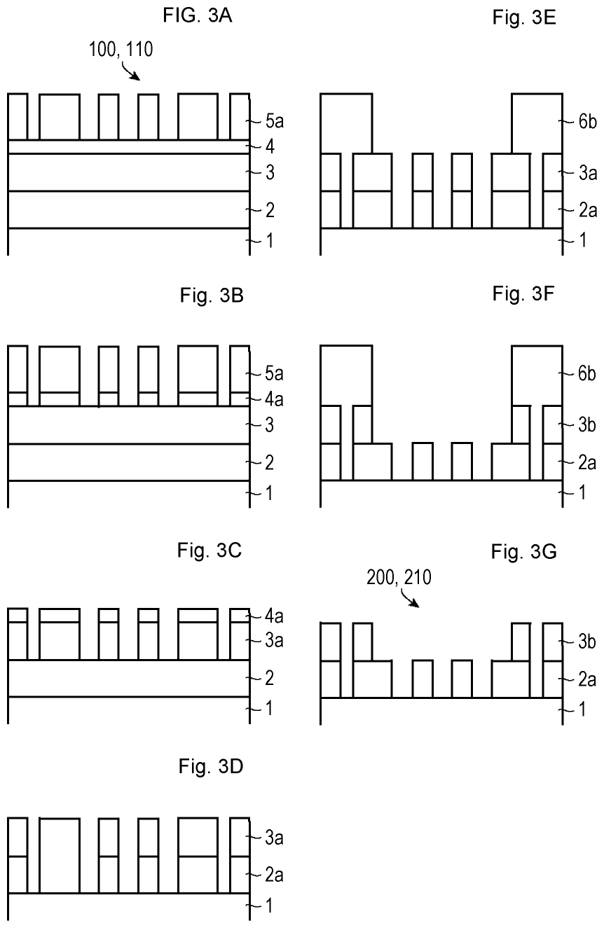

The mask blank 100 includes the light-shielding film 3 on the phase shift film 2. In general, in the phase shift mask, an outer peripheral region of a region in which a transfer pattern is formed (transfer pattern formation region) is expected to secure optical density (OD) of a predetermined value or more so that the resist film is not affected by the exposure light transmitted through the outer peripheral region when transfer by exposure is performed on the resist film on a semiconductor wafer using an exposure apparatus. The outer peripheral region of the phase shift mask preferably has OD of 2.8 or more, and more preferably has OD of 3.0 or more. As described above, the phase shift film 2 has a function of transmitting the exposure light with predetermined transmittance, and it is difficult to secure the optical density of a predetermined value only with the phase shift film 2. Therefore, it is expected to layer the light-shielding film 3 on the phase shift film 2 at a stage of manufacturing the mask blank 100 in order to secure optical density that would otherwise be insufficient. With such a configuration of the mask blank 100, it is possible to manufacture a phase shift mask 200 in which the optical density of a predetermined value is secured in the outer peripheral region by removing, in the course of manufacturing the phase shift mask 200 (refer to FIGS. 3A-3G), the light-shielding film 3 in a region where the phase shift effect is to be used (basically, the transfer pattern formation region).

Either a single-layer structure or a stacked structure including two or more layers is applicable to the light-shielding film 3. Each layer of the light-shielding film 3 having the single-layer structure and the light-shielding film 3 having the stacked structure including two or more layers may have substantially the same composition in a thickness direction of the film or the layer, or may have composition having a gradient in the thickness direction of the layer.

The mask blank 100 in the embodiment illustrated in FIG. 1 has a configuration in which the light-shielding film 3 is layered on the phase shift film 2 without another film interposed therebetween. The light-shielding film 3 in this configuration is expected to be made of a material having sufficient etching selectivity with respect to an etching gas used during a pattern formmation on the phase shift film 2. The light-shielding film 3 in this case is preferably formed of a material containing chromium. Examples of the material containing chromium that forms the light-shielding film 3 include chromium metal, and a material containing, in addition to chromium, one or more elements selected from oxygen, nitrogen, carbon, boron, and fluorine.

Generally, a chromium-based material is etched with a mixed gas of a chlorine-based gas and oxygen gas, but chromium metal has an etching rate not that high for this etching gas. In order to increase the etching rate for the etching gas of the mixed gas of the chlorine-based gas and oxygen gas, the material for forming the light-shielding film 3 is preferably the material containing, in addition to chromium, one or more elements selected from oxygen, nitrogen, carbon, boron, and fluorine. One or more elements out of molybdenum, indium, and tin may be contained in the material containing chromium that forms the light-shielding film 3. Containing one or more elements out of molybdenum, indium, and tin makes it possible to further increase the etching rate for the mixed gas of the chlorine-based gas and oxygen gas.

When the hard mask film 4 to be described later is formed of a material containing chromium on the light-shielding film 3, the light-shielding film 3 may be formed of a material containing silicon. In particular, a material containing a transition metal and silicon has high light-shielding performance, and thereby the thickness of the light-shielding film 3 can be reduced. Examples of the transition metal contained in the light-shielding film 3 include any one metal of molybdenum (Mo), tantalum (Ta), tungsten (W), titanium (Ti), chromium (Cr), nickel (Ni), vanadium (V), zirconium (Zr), ruthenium (Ru), rhodium (Rh), zinc (Zn), niobium (Nb), palladium (Pd) and the like, or an alloy of these metals. Examples of a metal element other than a transition metal element contained in the light-shielding film 3 include aluminum (Al), indium (In), tin (Sn), gallium (Ga) and the like.

On the other hand, the light-shielding film 3 may have a structure in which a layer containing chromium and a layer containing the transition metal and silicon are layered in this order from the phase shift film 2 side. Specific matters of the materials of the layer containing chromium and the layer containing the transition metal and silicon in this case are the same as those in the case of the light-shielding film 3 described above.

### [Hard Mask Film]

The hard mask film 4 is provided in contact with a surface of the light-shielding film 3. The hard mask film 4 is a film formed of a material having etching resistance to the etching gas used during an etching of the light-shielding film 3. It is sufficient that the hard mask film 4 has a film thickness enough to serve as an etching mask until the dry etching for forming a pattern on the light-shielding film 3 is finished, and basically, the hard mask film 4 is not limited in optical characteristic. Therefore, the hard mask film 4 can be made significantly thinner than the light-shielding film 3.

In a case where the light-shielding film 3 is formed of the material containing chromium, the hard mask film 4 is preferably formed of a material containing silicon. Since the hard mask film 4 in this case tends to have low adhesion to a resist film of an organic material, it is preferable to perform hexamethyldisilazane (HMDS) treatment on a surface of the hard mask film 4 to improve the adhesion of the surface. The hard mask film 4 in this case is more preferably formed of SiO₂, SiN, SiON or the like.

In addition to the above, a material containing tantalum is also applicable as the material of the hard mask film 4 in a case where the light-shielding film 3 is formed of the material containing chromium. Examples of the material containing tantalum in this case include tantalum metal and a material and the like which contains, in addition to tantalum, one or more elements selected from nitrogen, oxygen, boron, and carbon. Examples of the material include Ta, TaN, TaO, TaON, TaBN, TaBO, TaBON, TaCN, TaCO, TaCON, TaBCN, TaBOCN and the like, for example. In a case where the light-shielding film 3 is formed of the material containing silicon, the hard mask film 4 is preferably formed of the material containing chromium described above.

In the mask blank 100, a resist film of the organic material is preferably formed with a film thickness of 100 nm or less in contact with the surface of the hard mask film 4. In a case of a fine pattern corresponding to DRAM hp 32 nm generation, a sub-resolution assist feature (SRAF) having a line width of 40 nm might be provided in a transfer pattern (phase shift pattern) to be formed on the hard mask film 4. However, even in this case, since a cross-sectional aspect ratio of the resist pattern can be made as low as 1:2.5, it is possible to restrain collapse and detachment of the resist pattern during development, rinsing and the like of the resist film. The resist film more preferably has a film thickness of 80 nm or less.

### [Resist Film]

In the mask blank 100, the resist film of the organic material is preferably formed with a film thickness of 100 nm or less in contact with the surface of the hard mask film 4. In a case of a fine pattern corresponding to the DRAM hp 32 nm generation, a sub-resolution assist feature (SRAF) having a line width of 40 nm might be provided in a light-shielding pattern to be formed on the light-shielding film 3. However, even in this case, by providing the hard mask film 4 as described above, the film thickness of the resist film can be reduced, and a cross-sectional aspect ratio of the resist pattern formed by this resist film can be made as low as 1:2.5. Therefore, it is possible to restrain collapse and detachment of the resist pattern during development, rinsing and the like of the resist film. The resist film more preferably has a film thickness of 80 nm or less. The resist film is preferably a resist for electron beam drawing exposure, and more preferably a chemically amplified resist.

### Second Embodiment

FIG. 2 is a cross-sectional view illustrating a configuration of a mask blank 110 according to a second embodiment of the present disclosure. The mask blank 110 illustrated in FIG. 2 is different from the mask blank 100 illustrated in FIG. 1 in that a phase shift film 2 has a four-layer structure in which a fourth layer 24 is layered in addition to a first layer 21, a second layer 22, and a third layer 23, and that a light-shielding film 3 is provided on the fourth layer 24. Hereinafter, description of points common to the mask blank 100 of the first embodiment will be omitted as appropriate. A thickness of each layer of the phase shift film 2 illustrated in FIGS. 1 and 2 is illustrative as understood from the above description, and is not limited to the illustrated one.

The fourth layer 24 preferably contains silicon and oxygen, and more preferably consists of silicon and oxygen. In the fourth layer 24, in order to exhibit a function as a cap layer, a total content of silicon and oxygen is preferably 90 atom % or more, more preferably 95 atom % or more, and still more preferably 98 atom % or more.

A thickness of the fourth layer 24 is preferably more than 1 nm, and more preferably 2 nm or more in order to exhibit the function as the cap layer. In order to control a film thickness of the phase shift film 2 to be small, the thickness of the fourth layer 24 is preferably 10 nm or less, and more preferably 8 nm or less.

The mask blank 110 in the present embodiment has the four-layer structure in which the fourth layer 24 is provided as described above. The fourth layer 24 has a characteristic excellent in chemical resistance and cleaning resistance. Therefore, a thickness of the third layer 23 can be, for example, 4 nm or less even in a case where the phase shift film 2 is expected to have high chemical resistance and cleaning resistance.

Although the phase shift film 2 having the three-layer structure has been described in the first embodiment and the phase shift film 2 having the four-layer structure has been described in the second embodiment, the contents of the present disclosure are not limited thereto. The number of layers may be five or more as long as desired transmittance, phase difference, and film thickness are satisfied.

The phase shift film 2 in the mask blank 100 and 110 of the first and second embodiments can be patterned by three-stage or four-stage dry etching treatment using a chlorine-based gas and a fluorine-based gas. The first layer 21 and the third layer 23 are preferably patterned by dry etching using the chlorine-based gas, and the second layer 22 and the fourth layer are preferably patterned by dry etching using the fluorine-based gas. Etching selectivity is significantly high between the first layer 21 and the second layer 22, between the second layer 22 and the third layer 23, and between the third layer 23 and the fourth layer 24. Although not particularly limited, by performing etching treatment divided into multiple stages on the phase shift film 2 having the above-described characteristic, it is possible to reduce an influence of side etching to obtain an excellent pattern cross-sectional shape.

In general, when a pattern is formed on a thin film by dry etching, additional etching (so-called over etching) for enhancing perpendicularity of a sidewall of the pattern formed on the thin film is performed. Over etching is often set on the basis of a time, as a reference, when etching reaches a lower surface of the thin film, a so-called just etching time. By applying the etching treatment divided into multiple stages to the patterning of the phase shift film 2 as described above, the reference time for the over etching time can be set as the just etching time of the first layer 21 of the phase shift film 2. As a result, the over etching time can be shortened, and excellent etching depth uniformity can be obtained. Here, the chlorine-based gas is preferably a chlorine-based gas containing boron, more preferably BCl₃ gas, and still more preferably a mixed gas of BCl₃ gas and Cl₂ gas.

### [Manufacturing Procedure of Mask Blank]

The mask blank 100 and 110 having the above-described configuration is manufactured by the following procedure. First, a transparent substrate 1 is prepared. The transparent substrate 1 has an end face and a main surface polished to have predetermined surface roughness (for example, in an inner region of a square having a side of 1 μm, root mean square roughness Rq is 0.2 nm or less), and then subjected to predetermined cleaning treatment and drying treatment.

Next, on the transparent substrate 1, the phase shift film 2 is formed in order from the first layer 21, the second layer 22, the third layer 23, (and the fourth layer 24) by a sputtering method. The first layer 21, the second layer 22, the third layer 23, (and the fourth layer 24) in the phase shift film 2 are formed by sputtering, and it is possible to apply any sputtering such as DC sputtering, RF sputtering, and ion beam sputtering. In consideration of a film formation rate, it is preferable to apply the DC sputtering. In a case of using a target having low conductivity, it is preferable to apply the RF sputtering or ion beam sputtering. In consideration of the film formation rate, it is more preferable to apply the RF sputtering.

As for the first layer 21 and the third layer 23 of the phase shift film 2, any of a sputtering target containing hafnium and a sputtering target containing hafnium and oxygen can be applied.

As for the second layer 22 (and the fourth layer 24) of the phase shift film 2, any of a sputtering target containing silicon and a sputtering target containing silicon and oxygen can be applied.

After the phase shift film 2 is formed, annealing treatment at predetermined heating temperature is performed as appropriate. Next, the light-shielding film 3 described above is formed on the phase shift film 2 by the sputtering method. Then, the hard mask film 4 described above is formed on the light-shielding film 3 by the sputtering method. In film formation by the sputtering method, film formation is performed using the sputtering target containing materials forming the respective films described above at a predetermined composition ratio and a sputtering gas, and also using the mixed gas of the noble gas and the reactive gas described above as the sputtering gas as necessary. Thereafter, in a case where the mask blank 100 and 110 includes a resist film, hexamethyldisilazane (HMDS) treatment is performed on a surface of the hard mask film 4 as necessary. Then, the resist film is formed on the surface of the hard mask film 4 subjected to the HMDS treatment by a coating method such as a spin coating method to complete the mask blank 100 and 110.

In this manner, with the mask blank 100 and 110 of the first and second embodiments, the transmittance with respect to the exposure light can be increased to a certain level or more (for example, 35% or more) to enhance the phase shift effect, the film thickness of the phase shift film can be controlled to a certain level or less (for example, 60 nm or less), and the phase shift mask having excellent optical performance can be manufactured.

### <Phase Shift Mask and Manufacturing Method Thereof>

FIGS. 3A-3G illustrate the phase shift mask 200 and 210 according to the embodiments of the present disclosure manufactured from the mask blank 100 and 110 of the above-described embodiments, and a manufacturing process thereof. As illustrated in FIG. 3G, the phase shift mask 200 and 210 is characterized in that a phase shift pattern 2a that is a transfer pattern is formed on the phase shift film 2 of the mask blank 100, and that a light-shielding pattern 3b having a pattern including a light-shielding band is formed on the light-shielding film 3. The phase shift mask 200 and 210 has a technical feature which is the same as that of the mask blank 100 and 110. Matters regarding the transparent substrate 1, the first layer 21, the second layer 22, the third layer 23, (and the fourth layer 24) of the phase shift film 2, and the light-shielding film 3 in the phase shift mask 200 and 210 are the same as those of the mask blank 100 and 110. The hard mask film 4 is removed in the course of production of the phase shift mask 200 and 210.

The method of manufacturing the phase shift mask 200 and 210 according to the embodiments of the present disclosure uses the mask blank 100 and 110 described above, and includes a process of forming a transfer pattern on the light-shielding film 3 by dry etching, a process of forming a transfer pattern on the phase shift film 2 by dry etching using the light-shielding film 3 having the transfer pattern as a mask, and a process of forming the light-shielding pattern 3b on the light-shielding film 3 by dry etching using the resist film (resist pattern 6b) having a light-shielding pattern as a mask. Hereinafter, a method of manufacturing the phase shift mask 200 and 210 of the present disclosure will be described according to the manufacturing process illustrated in FIGS. 3A-3G. Note that, the method of manufacturing the phase shift mask 200 and 210 using the mask blank 100 and 110 in which the hard mask film 4 is layered on the light-shielding film 3 is herein described. A case where a material containing chromium is applied to the light-shielding film 3 and a material containing silicon is applied to the hard mask film 4 is described.

First, the resist film is formed by a spin coating method in contact with the hard mask film 4 in the mask blank 100 and 110. Next, a first pattern that is a transfer pattern (phase shift pattern) to be formed on the phase shift film 2 is exposed and drawn with an electron beam on the resist film, and predetermined treatment such as development treatment is further performed to form a first resist pattern 5a having the phase shift pattern (refer to FIG. 3A). Subsequently, dry etching using a fluorine-based gas is performed using the first resist pattern 5a as a mask to form a first pattern (hard mask pattern 4a) on the hard mask film 4 (refer to FIG. 3B).

Next, after the resist pattern 5a is removed, dry etching using a mixed gas of a chlorine-based gas and an oxygen gas is performed using the hard mask pattern 4a as a mask to form a first pattern (light-shielding pattern 3a) on the light-shielding film 3 (refer to FIG. 3C). Subsequently, dry etching using a chlorine-based gas and dry etching using a fluorine-based gas are alternately performed using the light-shielding pattern 3a as a mask four times (three times in a case of the three-layer), a first pattern (phase shift pattern 2a) is formed on the phase shift film 2, and the hard mask pattern 4a is removed (refer to FIG. 3D). More specifically, dry etching using the chlorine-based gas is performed on the first layer 21 and the third layer 23, and dry etching using the fluorine-based gas is performed on the second layer 22 (and the fourth layer 24).

Next, the resist film was formed on the mask blank 100 and 110 by a spin coating method. Next, a second pattern that is a pattern (light-shielding pattern) to be formed on the light-shielding film 3 is exposed and drawn with an electron beam on the resist film, and predetermined treatment such as development treatment is further performed to form a second resist pattern 6b having the light-shielding pattern (refer to FIG. 3E). Subsequently, dry etching using a mixed gas of a chlorine-based gas and an oxygen gas is performed using the second resist pattern 6b as a mask to form a second pattern (light-shielding pattern 3b) on the light-shielding film 3 (refer to FIG. 3F). Furthermore, the second resist pattern 6b is removed, and the phase shift mask 200 and 210 is obtained through predetermined treatment such as cleaning (refer to FIG. 3G).

The chlorine-based gas used in the dry etching described above is not particularly limited as long as Cl is contained. Examples thereof include Cl₂, SiCl₂, CHCl₃, CH₂Cl₂, CCl₄, BCl₃ and the like, for example. The chlorine-based gas used in the dry etching for the first layer 21 and the third layer 23 described above preferably contains boron, and more preferably contains BCl₃. In particular, a mixed gas of a BCl₃ gas and a Cl₂ gas is preferable because an etching rate for hafnium is relatively high.

The phase shift mask 200 and 210 manufactured by the method of manufacturing illustrated in FIGS. 3A-3G is the phase shift mask provided with the phase shift film 2 (phase shift pattern 2a) having the transfer pattern on the transparent substrate 1.

By manufacturing the phase shift mask 200 and 210 as described above, the phase shift effect can be enhanced by increasing the transmittance with respect to the exposure light to a certain level (for example, 35% or more), the film thickness of the phase shift film can be kept to a certain level or less (for example, 60 nm or less), and the phase shift mask 200 and 210 having excellent optical performance can be obtained.

Then, an exposure margin can be secured when the phase shift mask 200 and 210 including the phase shift film is set in an exposure apparatus and exposure transfer is performed on a transfer target (such as a resist film on a semiconductor substrate).

In contrast, the etching process used in the above-described method of manufacturing the phase shift mask is not only applicable to the mask blank of the present disclosure, but also can be used in a wider range of applications. This can also be applied when forming a transfer pattern on a pattern-forming thin film in a mask blank including a pattern-forming thin film having a structure in which at least a layer containing hafnium and oxygen, a layer containing oxygen and silicon, and a layer containing hafnium and oxygen are layered in this order on a substrate. The method of manufacturing a transfer mask, which is a mode to which the above-described method of manufacturing a phase shift mask is applied, preferably has the following configuration.

That is, a method of manufacturing a transfer mask using a mask blank including a pattern-forming thin film on a substrate,
the pattern-forming thin film having a structure in which a 1A layer containing hafnium and oxygen, a 2A layer containing silicon and oxygen, and a 3A layer containing hafnium and oxygen are layered in this order from a side of the substrate, the method including:
a process of performing dry etching using a boron-containing chlorine-based gas to form a transfer pattern on the 3A layer;
a process of performing dry etching using a fluorine-based gas using the 3A layer on which the transfer pattern is formed as a mask to form a transfer pattern on the 2A layer; and
a process of performing dry etching using a boron-containing chlorine-based gas using the 2A layer on which the transfer pattern is formed as a mask to form a transfer pattern on the 1A layer.

Furthermore, the method of manufacturing a semiconductor device according to the present disclosure includes a process of performing exposure transfer of a transfer pattern to the resist film on the semiconductor substrate using the phase shift mask 200 and 210 described above.

Since the phase shift mask 200 and 210 and the mask blank 100 and 110 of the present disclosure have the above-described effects, when the phase shift mask 200 and 210 is set on a mask stage of the exposure apparatus using the ArF excimer laser as the exposure light and exposure transfer of the transfer pattern is performed to the resist film on the semiconductor device, the transfer pattern can be transferred to the resist film on the semiconductor device with high CD uniformity. Therefore, in a case where, using the pattern of the resist film as a mask, a lower layer film is dry-etched to form a circuit pattern, it is possible to form a highly accurate circuit pattern without a wiring short circuit or disconnection due to a decrease in CD uniformity.

### EXAMPLES

Hereinafter, Examples 1 and 2 and Comparative Example 1 for more specifically describing the embodiments of the present disclosure are described.

### Example 1

### [Manufacture of Mask Blank]

Referring to FIG. 1, a transparent substrate 1 made of synthetic quartz glass having a main surface dimension of about 152 mm×about 152 mm and a thickness of about 6.35 mm was prepared. The transparent substrate 1 has an end face and a main surface polished to have predetermined surface roughness (Rq: 0.2 nm or less), and then subjected to predetermined cleaning treatment and drying treatment. When each optical characteristic of the transparent substrate 1 was measured using a spectroscopic ellipsometer (M-2000D manufactured by J. A. Woollam Company), a refractive index and an extinction coefficient with respect to light having a wavelength of 193 nm were 1.556 and respectively.

Next, the transparent substrate 1 was placed in a single wafer type RF sputtering apparatus, and a phase shift film 2 including a first layer 21 including hafnium and oxygen, a second layer 22 including silicon and oxygen, and a third layer 23 including hafnium and oxygen was formed on the transparent substrate 1 by sputtering (RF sputtering) using an argon (Ar) gas as a sputtering gas by alternately using an HfO₂ target and an SiO₂ target. A thickness D₁ of the first layer 21 was 36.5 nm, a thickness D₂ of the second layer 22 was 15.5 nm, a thickness D₃ of the third layer 23 was 6.1 nm, and a thickness of the phase shift film 2 was 58.1 nm. The thicknesses D₁ to D₃ of the first layer 21 to the third layer 23 satisfy all expressions (Expression 2-A) to (Expression 2-D) (the thicknesses D₁ to D₃ of the first layer 21 to the third layer 23 are within a range I-A and a range I-B).

Next, the transparent substrate 1 on which the phase shift film 2 was formed was subjected to heat treatment for reducing a film stress of the phase shift film 2. Using a phase shift amount measurement apparatus (MPM193 manufactured by Lasertec Corporation), transmittance with respect to light having a wavelength of 193 nm and a phase difference of the phase shift film 2 after the heat treatment were measured; the transmittance was 44.8% and the phase difference was 176.8 degrees (deg). When each optical characteristic of the phase shift film 2 was measured using a spectroscopic ellipsometer (M-2000D manufactured by J. A. Woollam Company), the refractive index n and the extinction coefficient k of the first layer 21 and the third layer 23 with respect to light having a wavelength of 193 nm were 2.93 and 0.24, respectively, and the refractive index n and the extinction coefficient k of the second layer 22 were 1.56 and 0.00, respectively.

Next, the transparent substrate 1 on which the phase shift film 2 was formed was placed in the single wafer type RF sputtering apparatus, and reactive sputtering (RF sputtering) was performed in a mixed gas atmosphere of argon (Ar), carbon dioxide (CO₂), and helium (He) using a chromium (Cr) target. Thus, a light-shielding film (CrOC film) 3 made of chromium, oxygen, and carbon was formed with a film thickness of 49 nm in contact with the phase shift film 2.

Next, the transparent substrate 1 on which the light-shielding film (CrOC film) 3 described above was formed was subjected to heat treatment. After the heat treatment, optical density at the wavelength (about 193 nm) of the light of the ArF excimer laser having a stack of the phase shift film 2 and the light-shielding film 3 was measured for the transparent substrate 1 on which the phase shift film 2 and the light-shielding film 3 were layered using a spectrophotometer (Cary 4000 manufactured by Agilent Technologies, Inc.), and it was confirmed that the optical density was 3.0 or more.

Next, the transparent substrate 1 on which the phase shift film 2 and the light-shielding film 3 were layered was placed in the single wafer type RF sputtering apparatus, and a hard mask film 4 including silicon and oxygen was formed with a thickness of 12 nm on the light-shielding film 3 by RF sputtering using a silicon dioxide (SiO₂) target and using an argon (Ar) gas as a sputtering gas. Furthermore, predetermined cleaning treatment was performed to manufacture a mask blank 100 of Example 1.

### [Manufacture of Phase Shift Mask]

Next, using the mask blank 100 of Example 1, a halftone phase shift mask 200 of Example 1 was manufactured by the following procedure. First, a surface of the hard mask film 4 was subjected to HMDS treatment. Subsequently, a resist film made of a chemically amplified resist for electron beam drawing was formed with a film thickness of nm in contact with the surface of the hard mask film 4 by a spin coating method. Next, a first pattern that is a phase shift pattern to be formed on the phase shift film 2 was drawn on the resist film with an electron beam, and predetermined development treatment and cleaning treatment were performed thereon to form a resist pattern 5a having a first pattern (refer to FIG. 3A).

Next, dry etching using a CF₄ gas was performed using the resist pattern 5a as a mask to form a first pattern (hard mask pattern 4a) on the hard mask film 4 (refer to FIG. 3B).

Next, the resist pattern 5a was removed. Subsequently, dry etching using a mixed gas of a chlorine gas (Cl₂) and an oxygen gas (O₂) was performed using the hard mask pattern 4a as a mask to form a first pattern (light-shielding pattern 3a) on the light-shielding film 3 (refer to FIG. 3C).

Next, dry etching was performed using the light-shielding pattern 3a as a mask to form a first pattern (phase shift pattern 2a) on the phase shift film 2, and at the same time, the hard mask pattern 4a was removed (refer to FIG. 3D). At that time, dry etching was performed on the first layer 21 and the third layer 23 using a mixed gas of a BCl₃ gas and a Cl₂ gas, and dry etching was performed on the second layer 22 using dry etching using a fluorine-based gas (a mixed gas of SF₆ and He).

Next, a resist film made of a chemically amplified resist for electron beam drawing was formed on the light-shielding pattern 3a with a film thickness of 150 nm by a spin coating method. Next, a second pattern that is a pattern (pattern including a light-shielding band pattern) to be formed on the light-shielding film is exposed and drawn on the resist film, and predetermined treatment such as development treatment is further performed to form a resist pattern 6b having the light-shielding pattern (refer to FIG. 3E). Subsequently, dry etching using a mixed gas of a chlorine gas (Cl₂) and an oxygen gas (O₂) was performed using the resist pattern 6b as a mask to form a second pattern (light-shielding pattern 3b) on the light-shielding film 3 (refer to FIG. 3F). Furthermore, the resist pattern 6b was removed, and the phase shift mask 200 was obtained through predetermined treatment such as cleaning (refer to FIG. 3G).

### [Evaluation of Pattern Transfer Performance]

The phase shift mask 200 produced through the above-described procedure was subjected to simulation of a transfer image at the time of exposure transfer to a resist film on a semiconductor device with exposure light of a wavelength of 193 nm using AIMS 193 (manufactured by Carl Zeiss AG). Verification of an exposure transfer image of this simulation showed that the CD uniformity was high and a design specification was sufficiently satisfied. From this result, it can be said that a circuit pattern finally formed on the semiconductor device can be formed with high accuracy even if the phase shift mask 200 of Example 1 is set on the mask stage of the exposure apparatus and exposure transfer is performed to the resist film on the semiconductor device.

### Example 2

### [Manufacture of Mask Blank]

A mask blank 110 of Example 2 was manufactured by a procedure similar to that in Example 1 except for a phase shift film 2. The phase shift film 2 of Example 2 is formed under different film forming conditions from those of the phase shift film 2 of Example 1. Specifically, the phase shift film 2 has a four-layer structure in which a fourth layer 24 is layered in addition to a first layer 21, a second layer 22, a third layer 23, and a thickness of each layer is changed. A transparent substrate 1 was placed in a single wafer type RF sputtering apparatus, and the phase shift film 2 including the first layer 21 including hafnium and oxygen, the second layer 22 including silicon and oxygen, the third layer 23 including hafnium and oxygen, and the fourth layer 24 including silicon and oxygen was formed on the transparent substrate 1 by sputtering (RF sputtering) using an argon (Ar) gas as a sputtering gas by alternately using an HfO₂ target and an SiO₂ target. A thickness D₁ of the first layer 21 was 39.2 nm, a thickness D₂ of the second layer 22 was 12.3 nm, a thickness D₃ of the third layer 23 was 4.4 nm, a thickness of the fourth layer 24 was 4.1 nm, and a thickness of the phase shift film 2 was 60.0 nm. The thicknesses D₁ to D₃ of the first layer 21 to the third layer 23 satisfy all expressions (Expression 1-A) to (Expression 1-D) (the thicknesses D₁ to D₃ of the first layer 21 to the third layer 23 are within a range I-A and a range I-B).

Next, the transparent substrate 1 on which the phase shift film 2 was formed was subjected to heat treatment for reducing a film stress of the phase shift film 2. Using a phase shift amount measurement apparatus (MPM193 manufactured by Lasertec Corporation), transmittance with respect to light having a wavelength of 193 nm and a phase difference of the phase shift film 2 after the heat treatment were measured; the transmittance was 42.9% and the phase difference was 177.4 degrees (deg). When each optical characteristic of the phase shift film 2 was measured using a spectroscopic ellipsometer (M-2000D manufactured by J. A. Woollam Company), the refractive index n and the extinction coefficient k of the first layer 21 and the third layer 23 with respect to light having a wavelength of 193 nm were 2.93 and 0.24, respectively, and the refractive index n and the extinction coefficient k of the second layer 22 and the fourth layer 24 were 1.56 and respectively.

Next, the light-shielding film (CrOC film) 3 made of chromium, oxygen, and carbon was formed with a film thickness of 51 nm in contact with the phase shift film 2 by the procedure similar to that in Example 1. For the transparent substrate 1 on which the phase shift film 2 and the light-shielding film 3 of Example 2 were layered, optical density at the wavelength (about 193 nm) of the light of the ArF excimer laser having a stack of the phase shift film 2 and the light-shielding film 3 was measured using a spectrophotometer (Cary 4000 manufactured by Agilent Technologies, Inc.), and it was confirmed that the optical density was 3.0 or more.

### [Manufacture and Evaluation of Phase Shift Mask]

Next, using the mask blank 110 of Example 2, a phase shift mask 210 of Example 2 was manufactured by the procedure similar to that in Example 1. Similarly to Example 1, the phase shift mask 210 of Example 2 was subjected to simulation of a transfer image at the time of exposure transfer to a resist film on a semiconductor device with exposure light of a wavelength of 193 nm using AIMS 193 (manufactured by Carl Zeiss AG). Verification of an exposure transfer image of this simulation showed that the CD uniformity was high and a design specification was sufficiently satisfied. From this result, it can be said that a circuit pattern finally formed on the semiconductor device can be formed with high accuracy even if the phase shift mask 200 of Example 2 is set on the mask stage of the exposure apparatus and exposure transfer is performed to the resist film on the semiconductor device.

### Comparative Example 1

### [Manufacture of Mask Blank]

A mask blank of Comparative Example 1 was manufactured by the procedure similar to that in Example 1 except for a film thickness of a phase shift film. The phase shift film of Comparative Example 1 was formed under different film forming conditions from those of the phase shift film 2 of Example 1. Specifically, a transparent substrate was placed in a single wafer type RF sputtering apparatus, and a phase shift film including a first layer including hafnium and oxygen, a second layer including silicon and oxygen, and a third layer including hafnium and oxygen was formed on the transparent substrate by sputtering (RF sputtering) using an argon (Ar) gas as a sputtering gas by alternately using an HfO₂ target and an SiO₂ target. A thickness D₁ of the first layer was 27.0 nm, a thickness D₂ of the second layer 22 was 14.0 nm, a thickness D₃ of the third layer 23 was 19.7 nm, and a thickness of the phase shift film 2 was 60.7 nm. The thicknesses D₁ to D₃ of the first layer to the third layer did not satisfy any of expressions (Expression 1-A) to (Expression 1-D) and (Expression 2-A) to (Expression 2-D) (the thicknesses D₁ to D₃ of the first layer to the third layer are out of ranges I-A and I-B and out of ranges II-A and II-B).

Using a phase shift amount measurement apparatus (MPM193 manufactured by Lasertec Corporation), transmittance with respect to light having a wavelength of 193 nm and a phase difference of the phase shift film were measured; the transmittance was 20.21% and the phase difference was 177.07 degrees (deg). When each optical characteristic of the phase shift film was measured using a spectroscopic ellipsometer (M-2000D manufactured by J. A. Woollam Company), the refractive index n and the extinction coefficient k of the first layer and the third layer with respect to light having a wavelength of 193 nm were 2.93 and 0.24, respectively, and the refractive index n and the extinction coefficient k of the second layer were 1.56 and 0.00, respectively.

Next, the light-shielding film (CrOC film) made of chromium, oxygen, and carbon was formed with a film thickness of 45 nm in contact with the phase shift film by the procedure similar to that in Example 1. For the transparent substrate on which the phase shift film and the light-shielding film of Comparative Example 1 were layered, optical density at the wavelength (about 193 nm) of the light of the ArF excimer laser having a stack of the phase shift film and the light-shielding film was measured using a spectrophotometer (Cary 4000 manufactured by Agilent Technologies, Inc.), and it was confirmed that the optical density was 3.0 or more.

### [Manufacture and Evaluation of Phase Shift Mask]

Next, using the mask blank of Comparative Example 1, a phase shift mask of Comparative Example 1 was manufactured by the procedure similar to that in Example 1. Similarly to Example 1, the phase shift mask of Comparative Example 1 was subjected to simulation of a transfer image at the time of exposure transfer to a resist film on a semiconductor device with exposure light of a wavelength of 193 nm using AIMS 193 (manufactured by Carl Zeiss AG). Verification of an exposure transfer image of this simulation showed that a design specification was not satisfied. This is presumed to be because the transmittance of the phase shift film could not be sufficiently increased, and the pattern could not be transferred clearly. From this result, it can be said that it is difficult to form a circuit pattern finally formed on a semiconductor device with high accuracy in a case where the phase shift mask of Comparative Example 1 is set on a mask stage of an exposure apparatus and exposure transfer is performed to a resist film on the semiconductor device.

### REFERENCE SIGNS LIST

1 Transparent substrate
2 Phase shift film
21 First layer
22 Second layer
23 Third layer
24 Fourth layer
2a Phase shift pattern
3 Light-shielding film
3a, 3b Light-shielding pattern
4 Hard mask film
4a Hard mask pattern
5a Resist pattern
6b Resist pattern
100, 110 Mask blank
200, 210 Phase shift mask

1. A mask blank comprising a phase shift film on a transparent substrate,
the phase shift film having a structure in which a first layer, a second layer, and a third layer are layered in this order on the transparent substrate,
the first layer and the third layer including hafnium and oxygen, and
the second layer including silicon and oxygen, wherein
when thicknesses of the first layer, the second layer, and the third layer are represented by D₁, D₂, and D₃, respectively, all relationships of (Expression 1-A) to (Expression 1-D) are satisfied, or all relationships of (Expression 2-A) to (Expression 2-D) are satisfied.
D₁≥4.88×10⁻⁴×D₂⁴−2.91×10⁻²×D₂³+0.647×D₂²−6.51×D₂+26.8 (Expression 1-A)
D₁≥−4.80×10⁻⁴×D₂⁴+2.86×10⁻²×D₂³−0.630×D₂²+5.97×D₂−10.0 (Expression 1-B)
D₃≥4.41×10⁻⁴×D₂⁴−2.66×10⁻²×D₂³+0.598×D₂²−6.13×D₂+59.3 (Expression 1-C)
D₃≤−4.72×10⁻⁴×D₂⁴+2.81×10⁻²×D₂³−0.625×D₂²+6.97×D₂+23.0 (Expression 1-D)
D₁≥5.14×10⁻⁴×D₂⁴−2.96×10⁻²×D₂³+0.634×D₂²−6.17×D₂+57.8 (Expression 2-A)
D₁≤−4.23×10⁻⁴×D₂⁴+2.57×10⁻²×D₂³−0.580×D₂²+5.71×D₂+25.8 (Expression 2-B)
D₃≥5.76×10⁻⁴×D₂⁴−3.23×10⁻²×D₂³+0.673×D₂²−6.33×D₂+23.7 (Expression 2-C)
D₃≤−4.76×10⁻⁴×D₂⁴+2.74×10⁻²×D₂³−0.579×D₂²+5.13×D₂−6.29 (Expression 2-D)

2. The mask blank according to claim 1, wherein the thickness D₂ of the second layer is 20 nm or less.

3. The mask blank according to claim 1, wherein a total content of hafnium and oxygen in each of the first layer and the third layer is 90 atom % or more.

4. The mask blank according to claim 1, wherein a total content of silicon and oxygen in the second layer is 90 atom % or more.

5. The mask blank according to claim 1, wherein a content of oxygen in each of the first layer, the second layer, and the third layer is 50 atom % or more.

6. The mask blank according to claim 1, wherein a refractive index n of each of the first layer and the third layer with respect to a wavelength of light of an ArF excimer laser is 2.5 or more and 3.1 or less.

7. The mask blank according to claim 1, wherein a refractive index n of the second layer with respect to a wavelength of light of an ArF excimer laser is 1.5 or more and 2.0 or less.

8. The mask blank according to claim 1, wherein an extinction coefficient k of each of the first layer and the third layer with respect to a wavelength of light of an ArF excimer laser is 0.05 or more and 0.4 or less.

9. The mask blank according to claim 1, wherein an extinction coefficient k of the second layer with respect to a wavelength of light of an ArF excimer laser is less than 0.05.

10. The mask blank according to claim 1, wherein the thickness of the third layer is 5 nm or more.

11. The mask blank according to claim 1, further comprising a fourth layer on the third layer, wherein a total content of silicon and oxygen in the fourth layer is 90 atom % or more.

12. The mask blank according to claim 1, wherein the phase shift film has a function of transmitting exposure light of an ArF excimer laser with transmittance of 35% or more, and a function of generating a phase difference of 150 degrees or more and 210 degrees or less between the exposure light transmitted through the phase shift film and the exposure light transmitted through air by the same distance as a thickness of the phase shift film.

13. A phase shift mask comprising a phase shift film on which a transfer pattern is formed on a transparent substrate,
the phase shift film having a structure in which a first layer, a second layer, and a third layer are layered in this order on the transparent substrate,
the first layer and the third layer including hafnium and oxygen, and
the second layer including silicon and oxygen, wherein
when thicknesses of the first layer, the second layer, and the third layer are represented by D₁, D₂, and D₃, respectively, all relationships of (Expression 1-A) to (Expression 1-D) are satisfied, or all relationships of (Expression 2-A) to (Expression 2-D) are satisfied.
D₁≥4.88×10⁻⁴×D₂⁴−2.91×10⁻²×D₂³+0.647×D₂²−6.51×D₂+26.8 (Expression 1-A)
D₁≥−4.80×10⁻⁴×D₂⁴+2.86×10⁻²×D₂³−0.630×D₂²+5.97×D₂−10.0 (Expression 1-B)
D₃≥4.41×10⁻⁴×D₂⁴−2.66×10⁻²×D₂³+0.598×D₂²−6.13×D₂+59.3 (Expression 1-C)
D₃≤−4.72×10⁻⁴×D₂⁴+2.81×10⁻²×D₂³−0.625×D₂²+6.97×D₂+23.0 (Expression 1-D)
D₁≥5.14×10⁻⁴×D₂⁴−2.96×10⁻²×D₂³+0.634×D₂²−6.17×D₂+57.8 (Expression 2-A)
D₁≤−4.23×10⁻⁴×D₂⁴+2.57×10⁻²×D₂³−0.580×D₂²+5.71×D₂+25.8 (Expression 2-B)
D₃≥5.76×10⁻⁴×D₂⁴−3.23×10⁻²×D₂³+0.673×D₂²−6.33×D₂+23.7 (Expression 2-C)
D₃≤−4.76×10⁻⁴×D₂⁴+2.74×10⁻²×D₂³−0.579×D₂²+5.13×D₂−6.29 (Expression 2-D)

14. The phase shift mask according to claim 13, wherein the thickness D₂ of the second layer is 20 nm or less.

15. The phase shift mask according to claim 13, wherein a total content of hafnium and oxygen in each of the first layer and the third layer is 90 atom % or more.

16. The phase shift mask according to claim 13, wherein a total content of silicon and oxygen in the second layer is 90 atom % or more.

17. The phase shift mask according to claim 13, wherein a content of oxygen in each of the first layer, the second layer, and the third layer is 50 atom % or more.

18. The phase shift mask according to claim 13, wherein a refractive index n of each of the first layer and the third layer with respect to a wavelength of light of an ArF excimer laser is 2.5 or more and 3.1 or less.

19. The phase shift mask according to claim 13, wherein a refractive index n of the second layer with respect to a wavelength of light of an ArF excimer laser is 1.5 or more and 2.0 or less.

20. The phase shift mask according to claim 13, wherein an extinction coefficient k of each of the first layer and the third layer with respect to a wavelength of light of an ArF excimer laser is 0.05 or more and 0.4 or less.

21. The phase shift mask according to claim 13, wherein an extinction coefficient k of the second layer with respect to a wavelength of light of an ArF excimer laser is less than 0.05.

22. The phase shift mask according to claim 13, wherein the thickness of the third layer is 5 nm or more.

23. The phase shift mask according to claim 13, further comprising a fourth layer on the third layer, wherein a total content of silicon and oxygen in the fourth layer is 90 atom % or more.

24. The phase shift mask according to claim 13, wherein the phase shift film has a function of transmitting exposure light of an ArF excimer laser with transmittance of 35% or more, and a function of generating a phase difference of 150 degrees or more and 210 degrees or less between the exposure light transmitted through the phase shift film and the exposure light transmitted through air by the same distance as a thickness of the phase shift film.

25. The phase shift mask according to claim 13, comprising a light-shielding film on which a light-shielding pattern is formed on the phase shift film.

26. A method of manufacturing a semiconductor device, the method comprising transferring a transfer pattern by exposure to a resist film on a semiconductor substrate using the phase shift mask according to claim 13.
